(19) United States
(12) Patent Application Publication
(10) Pub. No.: US 2021/0242342 A1
(43) Pub. Date: Aug. 5, 2021

(54) SEMICONDUCTOR DEVICE AND METHOD FOR MANUFACTURING SAME

(71) Applicant: DENSO CORPORATION, Kariya-city (JP)

(72) Inventors: KENTA GODA, Kariya-city (JP); YOUHEI ODA, Kariya-city (JP); YUSUKE NONAKA, Kariya-city (JP)

(21) Appl. No.: 17/237,343

(22) Filed: Apr. 22, 2021

Related U.S. Application Data
(63) Continuation of application No. PCT/JP2020/000490, filed on Jan. 9, 2020.

(30) Foreign Application Priority Data
Jan. 16, 2019 (JP) 2019-005485

(51) Int. Cl. H01L 29/78; H01L 29/423; H01L 29/66

(52) U.S. Cl. CPC H01L 29/7813; H01L 29/66734; H01L 29/4236

(57) ABSTRACT

The body region is formed between the plurality of trench gate structures, and the first impurity region is formed in a surface portion of the body region. The body region includes a second conductive type contact region having an impurity concentration of the second conductive type higher than the body region and contacting the upper electrode. The first impurity region includes a first conductive type contact region having the impurity concentration of the first conductive type impurity higher than the first impurity region and contacting the upper electrode. A second conductive type contact region is formed in a part of the body region where the first impurity region is not formed without forming the first conductive type contact region therein, and a contact trench is formed in the first impurity region. The first conductive type contact region is formed in the contact trench.

### CROSS REFERENCE TO RELATED APPLICATION

The present application is a continuation application of International Patent Application No. PCT/JP2020/000490 filed on Jan. 9, 2020, which designated the U.S. and claims the benefit of priority from Japanese Patent Application No. 2019-005485 filed on Jan. 16, 2019. The entire disclosures of all of the above applications are incorporated herein by reference.

### TECHNICAL FIELD

The present disclosure relates to a semiconductor device having a trench-type semiconductor switching element with a trench gate structure and a method for manufacturing the same.

### BACKGROUND

Conventionally, a semiconductor device having a trench-type MOSFET has been known. In this semiconductor device, a plurality of trench gate structures having a longitudinal direction in one direction are formed in the surface layer portion of the n⁻ type drift layer formed on the n⁺ type substrate, and the p type body layer and the n type source region are formed between the plurality of trench gate structures. A plurality of n type source regions are arranged along the longitudinal direction of the trench gate structure. Then, the n type contact region is formed at the center position of each n type source region, and the p type contact region is formed at the center position of the p type body region located between the n type source regions.

### SUMMARY

A body region is formed between the plurality of trench gate structures, and the first impurity region is formed in a surface portion of the body region. The body region includes a second conductive type contact region having an impurity concentration of the second conductive type higher than the body region and contacting the upper electrode. The first impurity region includes a first conductive type contact region having the impurity concentration of the first conductive type impurity higher than the first impurity region and contacting the upper electrode. A second conductive type contact region is formed in a part of the body region where the first impurity region is not formed without forming the first conductive type contact region therein, and a contact trench is formed in the first impurity region. The first conductive type contact region is formed in the contact trench.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a partial cross-sectional perspective view of the semiconductor device according to the first embodiment;

FIG. 2A is a cross-sectional view taken along a line IIA-IIA in FIG. 1;

FIG. 2B is a cross-sectional view taken along a line IIB-IIB in FIG. 1;

FIG. 3A is a cross-sectional view at a position passing through an n type impurity region in a semiconductor manufacturing apparatus having a structure that does not form a contact trench shown as a reference example;

FIG. 3B is a cross-sectional view of the semiconductor manufacturing apparatus shown in FIG. 3A at a position not passing through an n type impurity region;

FIG. 4A is a cross-sectional view at a position passing through an n type impurity region in a semiconductor manufacturing apparatus having a structure that forms a contact trench shown as a reference example; and

FIG. 4B is a cross-sectional view of the semiconductor manufacturing apparatus shown in FIG. 4A at a position not passing through an n type impurity region.

### DETAILED DESCRIPTION

Two types are adopted as the structures of the p type contact region and the n type contact region. One is a structure in which the surface of the p type body region and the surface of the n type source region have a planar shape, and the p type contact region and the n type contact region are formed on the plane (hereinafter referred to as the first structure). The other is a structure in which a contact trench is formed on the surface of a p type body region or an n type source region, and a p type contact region or an n type contact region is formed inside the contact trench (hereinafter referred to as a second structure).

However, in the case of the above structure, it was found that a difficulty may occur in any case.

Specifically, in the case of the first structure, a difficulty of lowering the avalanche withstand voltage may occur. When the L load is switched with a structure without a clamp diode, the MOSFET goes into avalanche operation. At this time, the electrons generated by the avalanche breakdown are extracted by the drain electrode, and the holes are extracted by the source electrode. However, in the case of the first structure, when the extracted holes pass through the p type body region, the potential of the region is increased. Therefore, the avalanche withstand voltage may be lowered.

On the other hand, in the case of the second structure, the saturation current density cannot be reduced when the load is short-circuited, which causes a difficulty of lowering the short-circuit withstand voltage. In order to improve the short circuit withstand voltage, it is necessary to reduce the saturation current density. This can be provided by dividing and forming the diffusion layer constituting the n type contact region and the p type contact region. Here, the saturation current density is determined by the width of the n type contact region. However, since a contact hole is formed in the interlayer insulating film and a contact trench or an n type contact region is formed using the contact hole as a mask, an n type contact region is also formed on the side surface of the trench on the p type body region side. Therefore, even in the p type body region, the n type contact region serves as an electron injection source, and the saturation current density cannot be reduced, so that the short-circuit tolerance is reduced.

According to example embodiments of the present disclosure, a semiconductor device capable of obtaining both an avalanche withstand voltage and a short circuit withstand voltage, and a method for manufacturing the same are provided.

According to an example embodiment, in a semiconductor device including a trench-type semiconductor switching element with a trench gate structure, the semiconductor switching element includes: a first conductive type drift layer; a second conductive type body region formed on the drift layer; a first conductive type first impurity region formed in a surface portion of the body region and having the higher impurity concentration than the drift layer; a plurality of trench structures in which a gate electrode layer is formed in each of trench via an insulation film, and each trench has one direction as a longitudinal direction and penetrating from the first impurity region and the body region to reach the drift layer; a first or second conductive type high impurity concentration layer formed on an opposite side of the body region with sandwiching the drift layer and having a higher impurity concentration than the drift layer; an upper electrode electrically connected to the first impurity region and the body region; and a lower electrode electrically connected to the high impurity concentration layer. In such a structure, the body region is formed between the plurality of trench gate structures, and the first impurity region is formed in a part of the surface portion of the body region, and the body region has a second conductive type contact region that has a higher concentration of the second conductive type impurity than the body region and is in contact with the upper electrode. Further, the first impurity region has a first conductive type contact region in which the concentration of the first conductive type impurity is higher than that of the first impurity region and is in contact with the upper electrode, and the body region has the surface with the flat shape at a portion thereof in which the first impurity region is not formed. The second conductive type contact region is formed on the surface with the flat shape. The contact trench is formed in the first impurity region, and the first conductive type contact region is formed in the contact trench.

In this way, with respect to the first impurity region, the first conductive type contact region and the upper electrode are electrically connected through the contact trench. Therefore, when the carrier generated by the avalanche breakdown is pulled out to the upper electrode while the avalanche operation is started, the carrier is pulled out by the path via the contact trench. Therefore, it is possible to suppress an increase in voltage in the body region and suppress a decrease in avalanche withstand voltage.

As for the body region, a second conductive type contact region is formed on the surface of the planar body region in which the first conductive type contact region is not formed, and the body region is electrically connected to the upper electrode through the second conductive type contact region. Therefore, when the load is short-circuited, the body region, which is disposed between the first impurity regions, does not include the first conductive type contact region as an injection source of the carrier, so that the saturation current density can be suppressed. Therefore, it is possible to suppress a decrease in the short-circuit tolerance.

Therefore, it is possible to obtain a semiconductor device capable of obtaining both an avalanche withstand voltage and a short circuit withstand voltage.

The reference numerals in parentheses attached to the components and the like indicate an example of correspondence between the components and the like and specific components and the like in an embodiment to be described below.

Embodiments of the present disclosure will be described below with reference to the drawings. In the following embodiments, the same reference numerals are assigned to parts that are the same or equivalent to each other to describe the same.

### First Embodiment

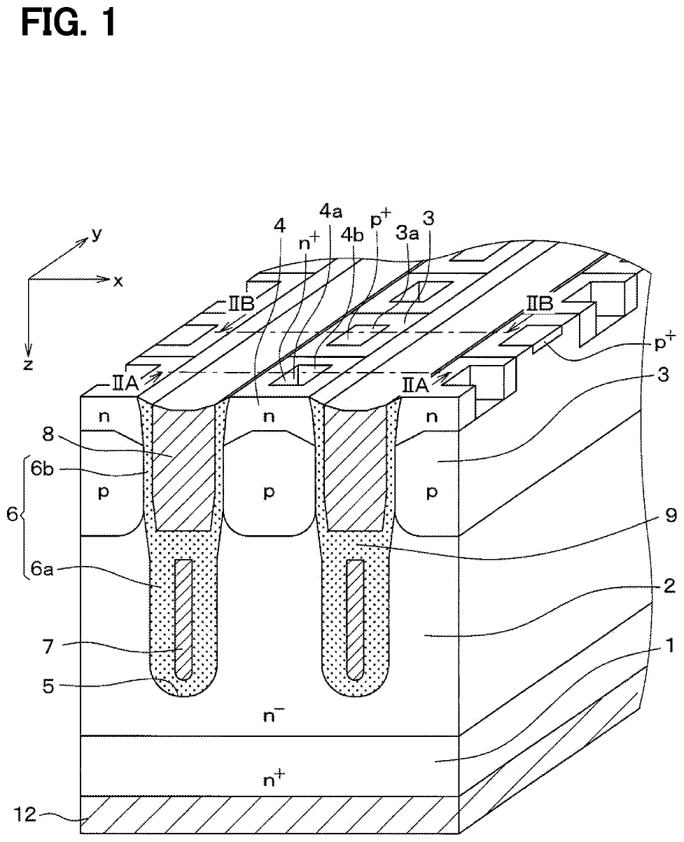

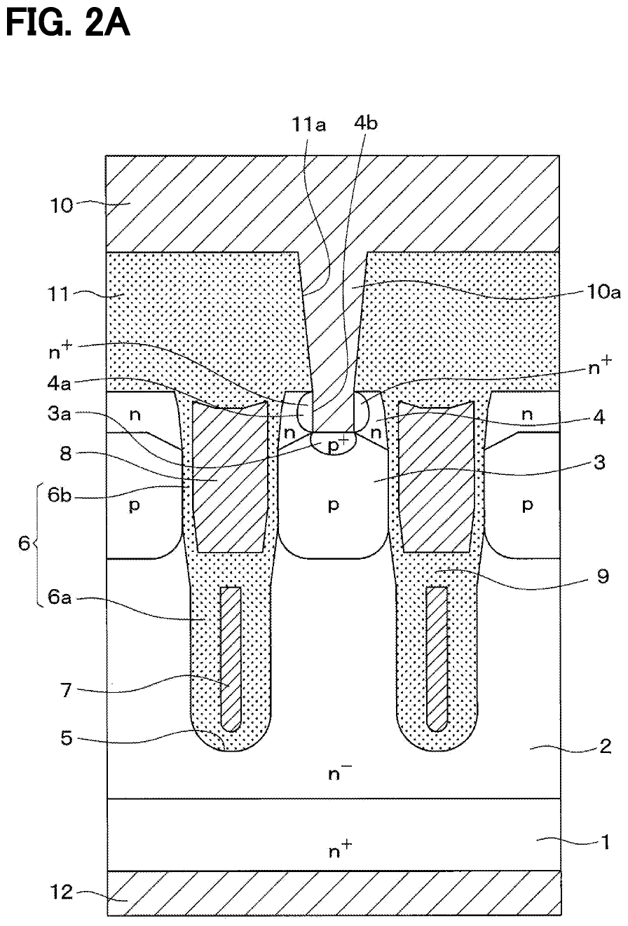

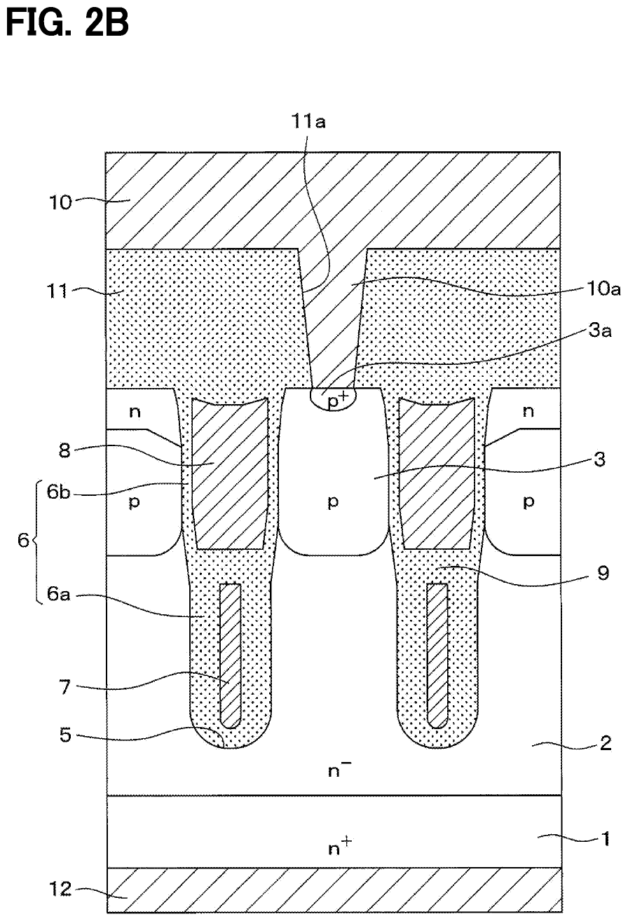

A first embodiment will be described. In the present embodiment, a semiconductor device provided with an n-channel type trench-type MOSFET will be described. Hereinafter, the structure of the semiconductor device according to the present embodiment will be described with reference to FIGS. 1, 2A, and 2B. The MOSFET shown in these drawings is formed in a cell area of the semiconductor device, and the semiconductor device is configured by forming an outer peripheral withstand voltage structure so as to surround the cell region, but only the MOSFET is shown in the drawing. In the following, as shown in FIG. 1, the description will be given such that a width direction of the MOSFET is an X direction, a length direction of the MOSFET crossing the X direction is a Y direction, and a thickness direction or a depth direction of the MOSFET, that is, the normal direction to the XY plane is a Z direction.

As shown in FIG. 1, the semiconductor device according to this embodiment is formed by using an n⁺ type semiconductor substrate 1 made of a semiconductor material such as silicon. On the surface of the n⁺ type semiconductor substrate 1, an n⁻ type drift layer 2 having an impurity concentration lower than that of the n⁺ type semiconductor substrate 1 is formed. The n⁺ type semiconductor substrate 1 constitutes a high impurity concentration layer having a high impurity concentration, and the semiconductor substrate 1 and the n⁻ type drift layer 2 provide a high impurity concentration layer and a drift layer having a lower impurity concentration than the high impurity concentration layer and disposed on one surface side thereof.

Further, a p type body region 3 having a relatively low impurity concentration is formed at a certain position in the surface layer portion of the n⁻ type drift layer 2. The p type body region 3 is formed by, for example, ion-implanting a p type impurity into the n⁻ type drift layer 2, and also functions as a channel layer for forming a channel region. As shown in FIG. 1, the p type body region 3 is formed with the y direction as the longitudinal direction among a plurality of trench gate structures described later.

An n type impurity region 4 corresponding to a source region having an impurity concentration higher than that of the n⁻ type drift layer 2 is provided in a surface layer portion of the p type body region 3. As shown in FIG. 1, the n type impurity region 4 has a configuration in which a plurality of separated n type impurity regions 4 are arranged in the y direction. In the present embodiment, the n type impurity regions 4 arranged in the y direction have the same size, have a rectangular upper surface shape, and are arranged at equal intervals. Further, the p type body region 3 is exposed between the n type impurity regions 4. A p⁺ type contact region 3a serving as a body contact is formed in the p type body region 3, and an n⁺ type contact region 4a serving as a source contact is formed in the n type impurity region 4.

More specifically, in the portion where the n type impurity region 4 is not formed, the surface of each p type body region 3 located between the n type impurity regions 4 has a planar shape, and a p⁺ type contact region 3a is formed at the center position of the above plane in the x direction. That is, the surface of each p type body region 3 located between the n type impurity regions 4 and the surface of the p⁺ type contact region 3a are disposed on the same plane. Then, this portion has a contact structure in which the n⁺ type contact region 4a described later is not formed.

On the other hand, in each n type impurity region 4, a contact trench 4b is formed in the central portion in the x direction, and an n⁺ type contact region 4a is formed so as to be exposed in the contact trench 4b. Further, in the case of the present embodiment, the contact trench 4b is formed to a depth that exposes the p type body region 3, and the p⁺ type contact region 3a is also formed on the surface portion of the exposed p type body region 3.

In the case of the present embodiment, the p⁺ type contact region 3a is formed at the center position of the portion of the p type body region 3 located between then type impurity regions 4 and has a rectangular surface shape. Further, the n⁺ type contact region 4a is formed at the center position of each n type impurity region 4, and has a rectangular surface shape.

Further, a plurality of gate trenches 5 having a longitudinal direction in one direction are formed between p type body regions 3 and between n type impurity regions 4 in the surface layer portion of the n⁻ type drift layer 2. The gate trench 5 is a trench for forming a trench gate structure, and in the present embodiment, the gate trenches 5 are arranged in parallel at equal intervals to form a striped layout.

The gate trench 5 is deeper than the p type body region 3, that is, the depth is set to reach the n⁻ type drift layer 2 from the substrate surface side through the n type impurity region 4 and the p type body region 3. Further, in the present embodiment, the width of the gate trench 5 gradually narrows toward the bottom, and the bottom is rounded.

The inner wall surface of the gate trench 5 is covered with an insulation film 6. The insulation film 6 may include a single film, but in the case of the present embodiment, the insulation film 6 includes the shield insulation film 6a covering the lower portion of the gate trench 5 and the gate insulation film 6b covering the upper portion thereof. The shield insulation film 6a covers the side surface of the lower portion from the bottom of the gate trench 5, and the gate insulation film 6b covers the side surface of the upper portion of the gate trench 5. In the present embodiment, the shield insulation film 6a is formed thicker than the gate insulation film 6b.

Further, in the gate trench 5, a shield electrode 7 and a gate electrode layer 8 made of doped Poly-Si are stacked via an insulation film 6 to form a two-layer structure. The shield electrode 7 is fixed to a source potential to reduce a capacitance between a gate and a drain and improve the electrical properties of the vertical type MOSFET. The gate electrode layer 8 performs a switching operation of the vertical MOSFET, and forms a channel region in the p type body region 3 on the side surface of the gate trench 5 when a gate voltage is applied.

An intermediate insulation film 9 is formed between the shield electrode 7 and the gate electrode layer 8, and the shield electrode 7 and the gate electrode layer 8 are insulated by the intermediate insulation film 9. The trench 5, the gate insulation film 6, the shield electrode 7, the gate electrode layer 8, and the intermediate insulation film 9 configure a trench gate structure. This trench gate structure has, for example, a striped layout in which a plurality of trench gate structures are arranged in the left-right direction of the drawings of FIGS. 2A and 2B with the vertical direction of the drawings of FIGS. 2A and 2B as the longitudinal direction.

Further, although not shown, at both ends of the gate trench 5 in the longitudinal direction, specifically, at the ends on the front side and the other side of the drawings in FIGS. 2A and 2B, the shield electrode 7 is formed to extend to the outside of the gate electrode layer 8. Then, those portions are exposed from the surface side of the p type body region 3 and the n type impurity region 4 as a shield liner.

The interlayer insulation film 11 made of an oxide film or the like is formed so as to cover the gate electrode layer 8, and an upper electrode 10 corresponding to a source electrode and the gate wiring not shown are formed on the interlayer insulation film 11. The upper electrode 10 is in contact with the p⁺ type contact region 3a and the n⁺ type contact region 4a through a connection portion 10a such as a tungsten (W) plug embedded in the contact hole 11a formed in the interlayer insulation film 11. As a result, the upper electrode 10 is electrically connected to the n type impurity region 4 and the p type body region 3. The gate wiring is also electrically connected to the gate electrode layer 8 through a contact hole formed in the interlayer insulation film 11.

Further, a lower electrode 12 corresponding to a drain electrode is formed on a surface of the n⁺ type semiconductor substrate 1 opposite to the n⁻ type drift layer 2. The configuration described above configures a basic structure of the vertical MOSFET. A cell region is formed by forming a plurality of vertical MOSFETs providing a plurality of cells.

As described above, the semiconductor device having the vertical MOSFET is formed. Next, a method of manufacturing the semiconductor device according to the present embodiment will be described. However, in the semiconductor device according to the present embodiment, a manufacturing method different from the conventional one will be described, and the same portion as the conventional one will be described in a simplified manner.

First, by preparing the semiconductor substrate 1 and epitaxially growing the n⁻ type drift layer 2 on the surface of the semiconductor substrate 1, the substrate is prepared such that the n⁻ type drift layer 2 is formed on one surface side of the semiconductor substrate 1 corresponding to the high impurity concentration layer. Next, a hard mask (not shown) that opens the region to be formed of the gate trench 5 is arranged, and the gate trench 5 is formed by etching using the hard mask. Subsequently, after removing the hard mask, a shield insulation film 6a is formed on the surface of the n− type drift layer 2 including the inner wall surface of the gate trench 5 by thermal oxidation or the like. Then, the doped polysilicon is stacked on the shield insulation film 6a and then etched back, and the doped polysilicon is left only at the bottom of the gate trench 5 and the end of the gate trench 5 to form the shield electrode 7 and the shield liner.

Further, a portion of the shield insulation film 6a formed on the upper side surface of the gate trench 5 or on the surface of the n⁻ type drift layer 2 is etched and removed. Then, the insulation film is deposited by plasma CVD (chemical vapor deposition) or the like to cover the upper side of the shield electrode 7 and the upper side of the gate trench 5, and then etched using a mask so that only the part formed on the shield electrode 7 and the shield liner remains. As a result, the intermediate insulation film 9 is formed.

After that, the gate insulation film 6b is formed by forming an insulation film on the upper side surface of the gate trench 5 by thermal oxidation or the like. Then, the doped polysilicon is deposited again and then etched back to form the gate electrode layer 8 in the gate trench 5. As a result, a trench gate structure is formed.

After that, the p type body region 3 is formed by ion-implanting the p type impurities. After a mask, in which the area where the n type impurity region 4 is to be formed is opened, is placed, n type impurities are ion-implanted to form the n type impurity region 4.

Subsequently, an interlayer insulation film 11 made of an oxide film or the like is formed by CVD or the like, and then flattening and polishing is performed to flatten the surface of the interlayer insulation film 11. Then, a contact hole 11a is formed in the interlayer insulation film 11.

At this time, first, the contact hole 11a connected to the n type impurity region 4 is formed. That is, the interlayer insulation film 11 is covered with a hard mask, and the portion of the hard mask corresponding to the central position in the x direction in the n type impurity region 4 is opened by photoetching. Then, a contact hole 11a is formed in the interlayer insulation film 11 by etching using a hard mask as a mask. As a result, a part of the surface of the n type impurity region 4 is exposed, and the surface of the p type body region 3 remains covered with the interlayer insulation film 11. The contact hole 11a connected to the n type impurity region 4 formed at this time corresponds to the first contact hole.

Further, after removing the hard mask, an n type impurity is ion-implanted using the interlayer insulation film 11 as a mask to form an n⁺ type contact region 4a on the surface portion of the n type impurity region 4. Then, silicon etching is performed using the interlayer insulation film 11 as a mask to form a contact trench 4b at a position corresponding to the contact hole 11a, that is, a central position in the x direction in the n type impurity region 4. As a result, the n⁺ type contact region 4a is exposed on the side surface of the contact trench 4b, and the p type body region 3 is exposed on the bottom surface of the contact trench 4b.

Next, the interlayer insulation film 11 is covered with a hard mask, and the portion of the hard mask corresponding to the central position in the x direction in the p type body region 3 is opened by photoetching. As a result, a part of the surface of the p type body region 3 is exposed, and the surface of the n type impurity region 4 remains covered with the hard mask. Then, a remaining contact hole 11a is formed in the interlayer insulation film 11 by etching using a hard mask as a mask. The contact hole 11a connected to the p type body region 3 formed at this time corresponds to the second contact hole. As a result, the surface of the p type body region 3 is exposed. Then, by removing the hard mask, the contact hole 11a formed at a position corresponding to the surface of the interlayer insulation film 11 and the surface of the n type impurity region 4 is also exposed, and in this state, the interlayer insulation film 11 is used as a mask to perform the ion implantation with the p type impurity. As a result, on the surface of each p type body region 3 located between the n type impurity regions 4, that is, the surface of the p type body region 3 in the portion having a planar shape and the portion located at the bottom of the contact trench 4b, a p⁺ type contact region 3a is formed. After this, although not shown, a step of forming the connection portion 10a, a step of forming the upper electrode 10 and the gate liner, and a step of forming the lower electrode 12 are performed. In this way, the semiconductor device having the vertical MOSFET according to this embodiment is completed.

According to the semiconductor device configured as described above, the following effects can be obtained.

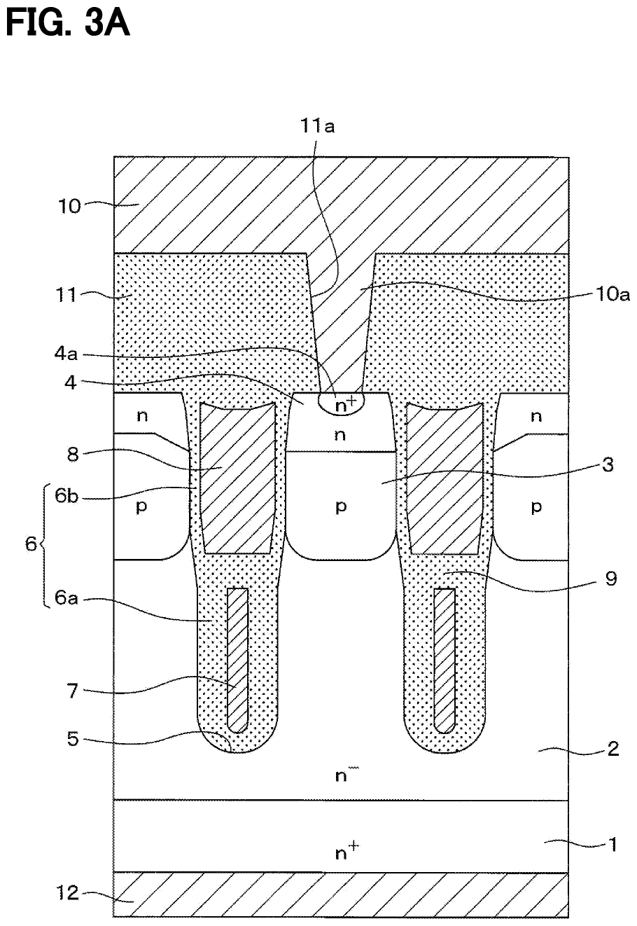

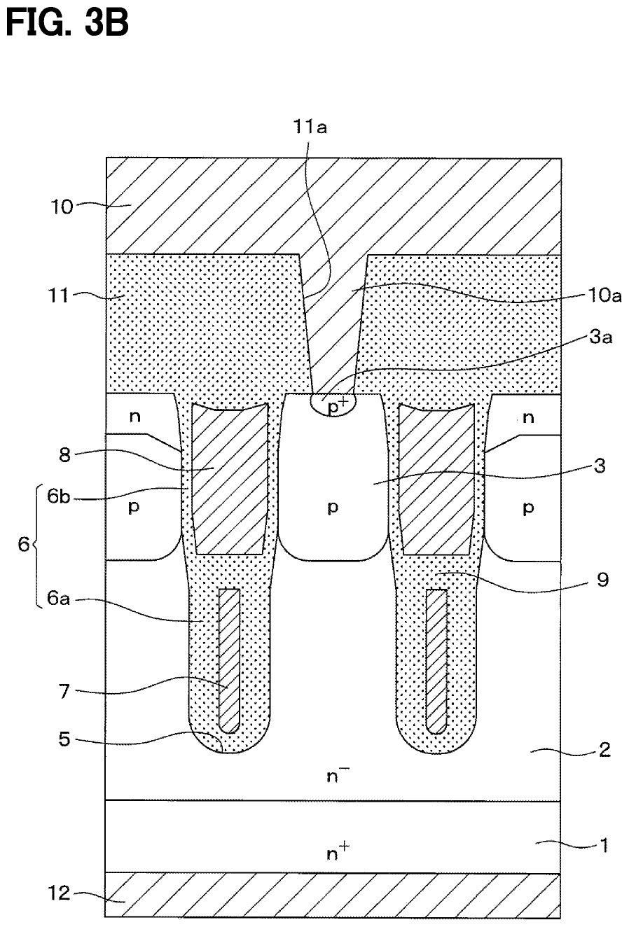

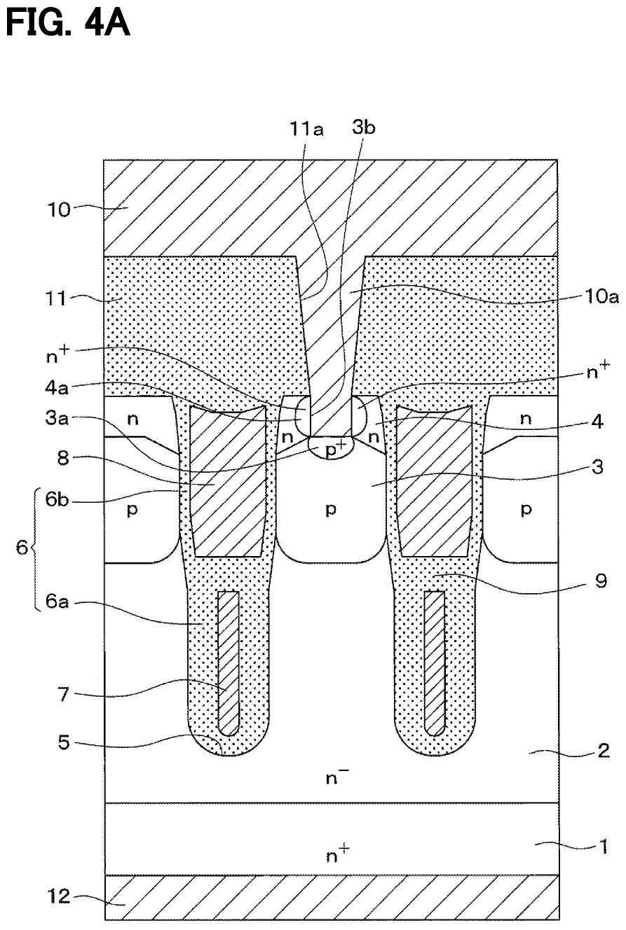

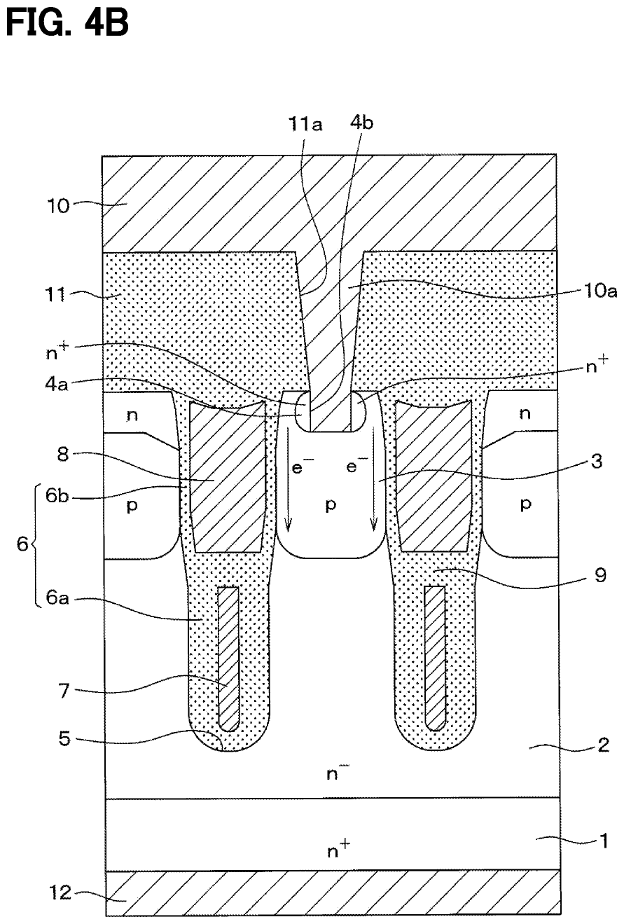

First, the conventional trench-type MOSFET has a first structure or a second structure. Specifically, the first structure is the structure shown in FIGS. 3A and 3B. That is, the first structure has a structure in which the surfaces of the p type body region 3 and the surface of the n type impurity region 4 have planar shapes, and the p⁺ type contact region 3a and the n⁺ type contact region 4a are formed on the plane. The second structure is the structure shown in FIGS. 4A and 4B. That is, the structure is such that the contact trenches 3b and 4b are formed on the surface of the p type body region 3 and the surface of the n type impurity region 4, and the p⁺ type contact regions 3a and the n⁺ type contact regions 4a are formed in the contact trenches 3b and 4b.

This is because, after the contact holes 11a are formed, the formation or non-formation of the contact trenches 3b and 4b is the same on both the p type body region 3 side and the n type impurity region 4 side. For this reason, there may be a difficulty that either the avalanche withstand voltage or the short circuit withstand voltage is lowered.

On the other hand, in the case of the present embodiment, in the n type impurity region 4, the n⁺ type contact region 4a and the upper electrode 10 are electrically connected through the contact trench 4b. Therefore, when the hole generated by the avalanche breakdown is pulled out to the upper electrode 10 while the avalanche operation is started, the hole is pulled out by the path via the contact trench 4b. Therefore, it is possible to suppress an increase in voltage in the p type body region 3 and suppress a decrease in avalanche withstand voltage.

Regarding the p type body region 3, a p⁺ type contact region 3a is formed on the surface of the planar p type body region 3 without the n⁺ type contact region 4a, and the body region 3 and the upper electrode 10 are electrically connected through the p⁺ type contact region 3a. Therefore, when the load is short-circuited, the n⁺ type contact region 4a, which is an electron injection source, does not exist in the p type body region 3 located between the n type impurity regions 4, and the saturation current density is suppressed. Therefore, it is possible to suppress a decrease in the short-circuit tolerance.

As described above, in the semiconductor device of the present embodiment, the contact trench 4b is formed in the n type impurity region 4, the p type body region 3 remains in a planar shape, and the upper electrode 10 is electrically connected. Therefore, it is possible to obtain a semiconductor device capable of obtaining both an avalanche withstand voltage and a short circuit withstand voltage.

### OTHER EMBODIMENTS

Although the present disclosure is made with reference to the embodiments described above, the present disclosure is not limited to such embodiments but may include various changes and modifications which are within equivalent ranges. In addition, various combinations and forms, and further, other combinations and forms including only one element, or more or less than these elements are also within the sprit and the scope of the present disclosure.

(1) For example, in the above embodiment, the high impurity concentration layer and the n⁻ type drift layer 2 are formed in the semiconductor substrate 1 by forming a high impurity concentration impurity region on the semiconductor substrate 1 and epitaxially growing the n⁻ type drift layer 2 on the impurity region. This is only an example of a case where a high impurity concentration layer is formed on the side opposite to the p type body region 3 with the drift layer sandwiched between them. Alternatively, the drift layer may be provided by the semiconductor substrate, and the ion implantation and the like is performed on the one side, so that the high impurity concentration layer may be formed.

(2) Further, in the above embodiment, the p type body region 3 arranged between the plurality of trench gate structures is formed along the y direction, and the n type impurity region 4 is divided into a plurality of n type impurity regions 4 in the y direction. This feature is just an example. That is, the present disclosure is applied to a structure in which an n type impurity region 4 is formed on a part of the surface portion of the p type body region 3. In that case, the surface of the portion of the p type body region 3 in which the n type impurity region 4 is not formed has a planar shape. The n type impurity region 4 is provided with the n⁺ type contact region 4a, and a part of the p type body region 3 is provided with the p⁺ type contact region 3a, and the part of the body region 3 has a planar shape in which the n type impurity region 4 is not formed. Then, each of them may be connected to the upper electrode 10.

(3) Further, in the above embodiment, the p⁺ type contact region 3a is formed at the center position in the x direction in the p type body region 3, and the n⁺ type contact region 4a is formed at the center position in the x direction in the n type impurity region 4. However, this is described as a preferable feature, and the arrangement location may shift due to the influence of mask misalignment or the like.

(4) In the embodiment described above, the MOSFET of the n-channel type trench gate structure in which the first conductive type is n-type and the second conductive type is p-type has been described as an example of the semiconductor switching element. However, this is merely an example, and a semiconductor switching element of another structure, for example, a MOSFET of a trench gate structure of a p-channel type in which the conductive type of each component is inverted with respect to the n-channel type may be used. In addition to the MOSFET, the present disclosure can be applied to an IGBT having a similar construction. In the IGBT case, except that the conductive type of the semiconductor substrate 1 is changed from the n type to the p type, the configuration is the same as the vertical MOSFET described in the embodiment described above. Further, in each of the above embodiments, the present disclosure is applied to a MOSFET having a trench gate structure having a two-layer structure in which a shield electrode 7 and a gate electrode layer 8 are stacked. Alternatively, the single layer structure of the gate electrode layer 8 may be applied.

(5) Further, in the above embodiment, the surface of the portion of the p type body region 3 in which the n type impurity region 4 is not formed has a planar shape. This is also merely an example, and a contact trench may be formed at this position as well, or a p⁺ type contact region 3a may be formed on the bottom surface of the contact trench. Also in this case, a mask is arranged so that the ion implantation when forming the n⁺ type contact region 4a is not performed in the portion of the p type body region 3 in which the n type impurity region 4 is not formed. Thus, the ion implantation may be formed with arranging the mask.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A semiconductor device comprising:
a trench type semiconductor switching element having a trench gate structure, wherein:
the semiconductor switching element includes:
a drift layer having a first conductive type;
a body region having a second conductive type and arranged on the drift layer;
a first impurity region having the first conductive type, arranged in a surface portion of the body region in the body region and having an impurity concentration higher than the drift layer;
a plurality of trench gate structures, each of which includes a trench having one direction as a longitudinal direction and reaching the drift layer from the first impurity region with penetrating the body region, and a gate electrode layer disposed in the trench via an insulation film;
a high impurity concentration layer having the first or second conductive type, arranged on a side opposite to the body region with sandwiching the drift layer therebetween, and having an impurity concentration higher than the drift layer;
an upper electrode electrically connected to the first impurity region and the body region; and
a lower electrode electrically connected to the high impurity concentration layer, wherein:
the body region is disposed between the plurality of trench gate structures;
the first impurity region is disposed in a surface portion of a part of the body region;
the body region includes a second conductive type contact region having an impurity concentration of the second conductive type higher than the body region and contacting the upper electrode;
the first impurity region includes a first conductive type contact region having the impurity concentration of the first conductive type impurity higher than the first impurity region and contacting the upper electrode;
the second conductive type contact region is disposed in a part of the body region where the first impurity region is not arranged, without arranging the first conductive type contact region therein;
a contact trench is arranged in the first impurity region; and
the first conductive type contact region is disposed in the contact trench.

2. The semiconductor device according to claim 1, wherein:
a part of the body region where the first impurity region is not arranged, has a flat surface; and
the second conductive type contact region is arranged on the flat surface without arranging the first conductive type contact region thereon.

3. The semiconductor device according to claim 2, wherein:
the body region is arranged between the plurality of trench gate structures along the longitudinal direction of the trench gate structures;
the first impurity region is divided into a plurality of portions arranged in the one direction;
the surface of the body region is a planar shape between the plurality of portions of the first impurity region; and
the second conductive type contact region is arranged on the surface with the planar shape.

4. The semiconductor device according to claim 3, wherein:
the second conductive type contact region is arranged at a center position of the body region between the plurality of first impurity regions in an arrangement direction of the plurality of trench gate structures; and
the contact trench is arranged at a center position of the first impurity region in the arrangement direction of the plurality of trench gate structures.

5. The semiconductor device according to claim 1, wherein:
the body region is exposed through the contact trench; and
the second conductive type contact region is arranged on a surface of the body region exposed through the contact trench.

6. The semiconductor device according to claim 1, wherein:
each trench gate structure has a two-layer structure in which a shield electrode and the gate electrode layer are stacked in each of the plurality of trenches via the insulation film.

7. A method for manufacturing a semiconductor device including a trench-type semiconductor switching element having a trench gate structure, the method comprising:
preparing a substrate having a high impurity concentration layer with a first conductive type or a second conductive type and a drift layer arranged on one surface side of the high impurity concentration layer, having the first conductive type and having an impurity concentration lower than the high impurity concentration layer;
forming a plurality of trench gate structures by forming a plurality of trenches with one direction as a longitudinal direction in the drift layer, and arranging a gate electrode layer in each of the plurality of trenches via an insulation film;
forming a body region having the second conductive type on the drift layer between the plurality of trenches;
forming a first impurity region having the first conductive type with an impurity concentration higher than the drift layer in a surface portion of a part of the body region in the body region;
forming an interlayer insulation film on the trench gate structure, the body region, and the first impurity region;
forming a contact hole connected to the body region and the first impurity region in the interlayer insulation film;
forming an upper electrode electrically connected to the first impurity region and the body region through the contact hole; and
forming a lower electrode electrically connected to the high impurity concentration layer, wherein:
the forming of the contact hole includes: forming a first contact hole connected to the first impurity region; and forming a second contact hole connected to a portion of the body region in which the first impurity region is not formed, the method further comprising:
after forming the first contact hole, ion implanting a first conductive type impurity using the interlayer insulation film as a mask to form the first conductive type contact region in the first impurity region;
forming a contact trench, exposing the first conductive type contact hole on a side surface of the contact trench, and exposing the body region on a bottom of the contact trench by etching the first impurity region including the first conductive type contact region through the first contact hole using the interlayer insulation film as a mask; and
after forming the second contact hole, ion implanting a second conductive type impurity using the interlayer insulation film as a mask to form a second conductive type contact region in the body region.
